(19) United States
(12) Patent Application Publication
(10) Pub. No.: US 2018/0115257 A1
(43) Pub. Date: Apr. 26, 2018

(54) MANUFACTURING METHOD AND APPLICATION FOR A QUANTUM SUPERCONDUCTOR RECTIFIER

(71) Applicant: FLOE CO., LTD., Taipei City (TW)

(72) Inventors: TOMMY LEE, Taipei City (TW); MARS JIAN, Keelung City (TW)

(21) Appl. No.: 15/331,328

(22) Filed: Oct. 21, 2016

(51) Int. Cl. H02M 11/00; H02M 7/04; H01L 39/02; H01L 39/24

(52) U.S. Cl. CPC H02M 11/00; H01L 39/24; H01L 39/02; H02M 7/04

(57) ABSTRACT

A manufacturing method and application for an quantum superconductor rectifier, wherein the quantum superconductor rectifier comprises: a carrier in a definite shape; wherein atomic nuclei in components of said carrier are excited to vibration by a strong magnetic field, thus when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken. Thereby interference by electrical resistance is reduced and more effectiveness is achieved.

### FIELD OF THE INVENTION

The present invention relates to a manufacturing method and application for a quantum superconductor rectifier, particularly to a manufacturing method and application for a quantum superconductor rectifier, wherein overloaded conductive molecules in a current loop are cut and separated and wherein the Van der Waals forces between the molecules are broken. Thereby interference by electrical resistance is reduced and more effectiveness is achieved.

### BACKGROUND OF THE INVENTION

Depreciation of vehicle parts is inevitable. Whenever a vehicle has left the factory, it weathered through climate, environment, temperature and humidity, while the body and internal motor performance depreciate by use, aging and mileage increase. At the same time, power and fuel-efficiency decrease and transport costs increase. Car maintenance cannot stop depreciation of motor performance. Current loop is also aged by the time. However changing circuit is expensive and not always helpful.

In view of these disadvantages the inventor tried the continuous testing and improvement and developed the present invention.

### SUMMARY OF THE INVENTION

The main object of the present invention is to provide a quantum superconductor rectifier, wherein interference by electrical resistance is reduced.

For achieving above object, the quantum superconductor rectifier comprises: a carrier in a definite shape; wherein atomic nuclei in components of said carrier are excited to vibration by a strong magnetic field, thus when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken. Thereby interference by electrical resistance is reduced and more effectiveness is achieved.

Preferably, the carrier is consisted of metallic materials.

Preferably, the carrier is consisted of copper alloy, aluminum alloy or titanium alloy.

Preferably, the carrier is covered with a case; wherein said case is made of insulation materials, thence it is insured that no leakage current is generated when a car battery is electronically connected.

Another object of the present invention is to provide a manufacturing method for a quantum superconductor rectifier, wherein manufacturing of a quantum superconductor rectifier is facilitated.

For achieving above object, the present invention comprises the following steps: (a) setting at least a carrier in the radio frequency field of an electromagnetic equipment, wherein a strong magnetic field is generated by the electromagnetic equipment, whereby atomic nuclei in components of said carrier are excited to vibration; (b) after a definite period, when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken. Thereby interference by electrical resistance is reduced and more effectiveness is achieved.

Another object of the present invention is to provide a kind of application of a quantum superconductor rectifier, which is inserted in a cigarette lighter in a car, whereby not only resistance of current loop of car is reduced, but also assembly is facilitated.

Another object of the present invention is to provide a kind of application of a quantum superconductor rectifier, which is electrically connected with a positive terminal of a car battery, whereby the resistance of current loop of car is reduced.

Another object of the present invention is to provide a kind of application of a quantum superconductor rectifier, which is electrically connected with a negative terminal of a car battery, whereby the resistance of current loop of car is reduced.

Another object of the present invention is to provide a kind of application of a quantum superconductor rectifier, which is set around power wires in an electric box, whereby the resistance of current loop of the electric box is reduced.

Another object of the present invention is to provide a kind of application of a quantum superconductor rectifier, which is set around wires of an electrical equipment, whereby the resistance of current loop of the electrical equipment is reduced.

Other aspects and advantages of the present invention will become apparent from the following, detailed description, taken in conjunction with the accompanying drawing, illustrating by way of example the principles of the present invention.

### BRIEF DESCRIPTION OF THE DRAWING

FIG. 1 is a perspective view of the quantum superconductor rectifier of the present invention.

FIG. 2 is a sectional view of the quantum superconductor rectifier of the present invention.

FIG. 3 shows a quantum superconductor rectifier of the present invention used in a cigarette lighter in car

FIG. 4 shows a quantum superconductor rectifier of the present invention used in the positive electrode of a car battery.

FIG. 5 shows a quantum superconductor rectifier of the present invention used between the negative electrode of a car battery and body.

FIG. 6 shows a quantum superconductor rectifier of the present invention used in an electric box.

FIG. 7 shows a quantum superconductor rectifier of the present invention used in an electrical equipment.

### DESCRIPTION OF THE PREFERRED EMBODIMENTS

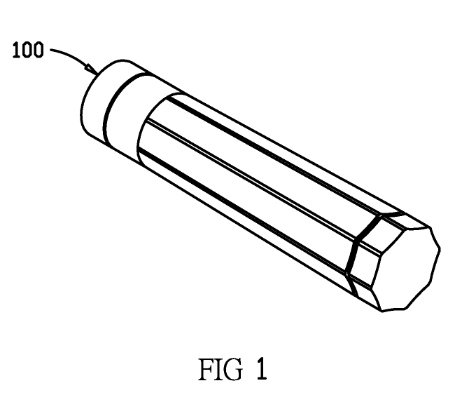

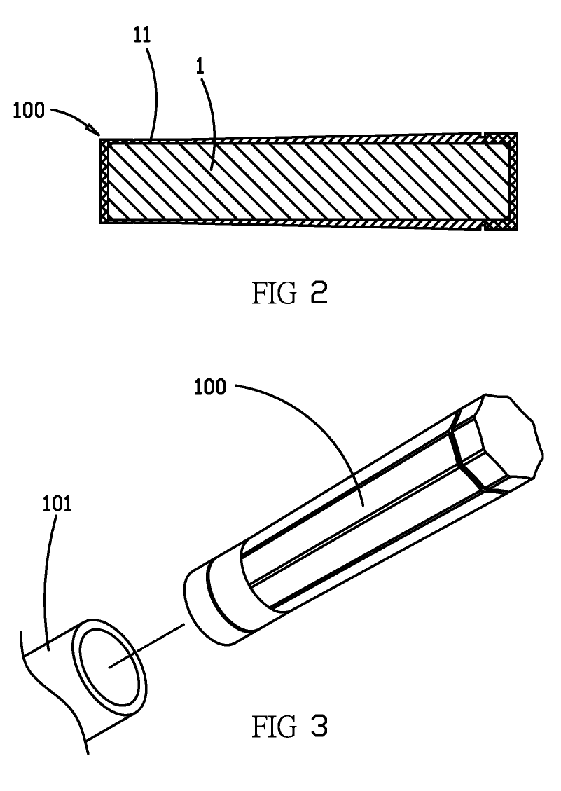

As shown in FIG. 1˜2, the quantum superconductor rectifier 100 of the present invention comprises: a carrier in a definite shape; wherein atomic nuclei in components of said carrier are excited to vibration by a strong magnetic field, thus when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken. Thereby interference by electrical resistance is reduced and more effectiveness is achieved.

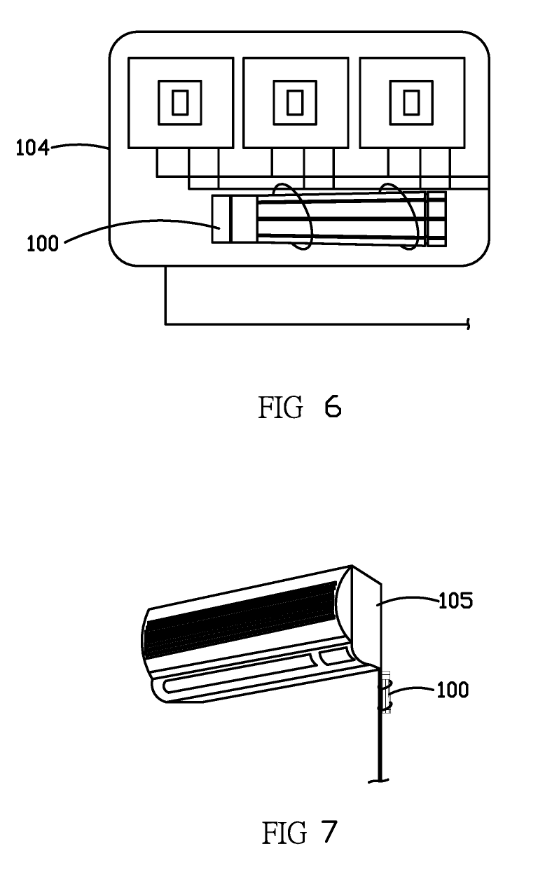

The carrier 1 is in definite shape, e.g. cylinder, which can be easily inserted in a cigarette lighter in car (as shown in FIG. 3) and which can also be easily set around wires (as shown in FIG. 6˜7), e.g. tied to the wires. Besides, the carrier 1 is made of any metallic materials, like copper alloy, aluminum alloy or titanium alloy and other metallic materials.

The carrier 1 can also be electrically connected with a car battery. In this case, the carrier 1 is covered with a case 11, wherein said case is made of insulation materials, thence it is insured that no leakage current is generated.

The said quantum superconductor rectifier is manufactured with a method including the following steps: (a) setting at least a carrier in the radio frequency field of an electromagnetic equipment, wherein a strong magnetic field is generated by the electromagnetic equipment, whereby atomic nuclei in components of said carrier are excited to vibration, (b) after a definite period, when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken. Thereby interference by electrical resistance is reduced and more effectiveness is achieved.

In the step (a), at least a carrier 1 is set in the radio frequency field of an electromagnetic equipment, wherein a strong magnetic field is generated by the electromagnetic equipment in the radio frequency field, whereby atomic nuclei in components of said carrier are excited to vibration; thereby, the atomic nuclei with magnetic moment are affected by the strong magnetic field to absorb appropriate frequency of electromagnetic radiation.

In the step (b), after a definite period, when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken. Thereby interference by electrical resistance is reduced and more effectiveness is achieved. Thereby, resonant frequency of atomic nuclei in molecules of the carrier 1 results a resonance spectra, after atomic nuclei have absorbed energy input in the strong magnetic field, angle between magnetic moment of atomic nuclei and strong magnetic field changes, whereby energy level transition happens and a signal from nuclear magnetic resonance results as a strong cutting line, wherein overloaded conductive molecules in a current loop are cut and separated and wherein the Van der Waals forces between the molecules are broken. Thereby interference by electrical resistance is reduced and more effectiveness is achieved.

Nuclear magnetic resonance and energy quantization are both conventional technology. However the conventional technology of nuclear magnetic resonance is applied to human testing, without accumulation by passing definite time for transmitting nuclear spectra of atomic nuclei in components of said carrier 1 and quantization of energy.

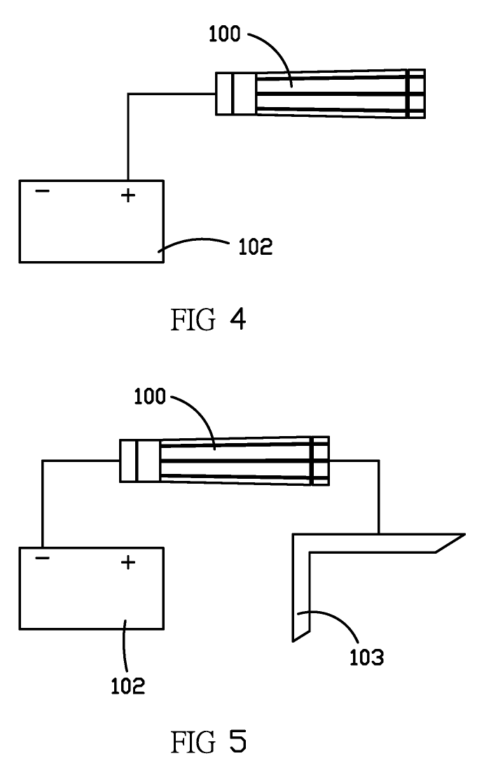

As shown in FIG. 3-5, the quantum superconductor rectifier 100 is applied to a car. As shown in FIG. 3, the quantum superconductor rectifier 100 is inserted in a cigarette lighter in car 101, whereby not only resistance of current loop of car is reduced, but also assembly is facilitated. As shown in 4, the quantum superconductor rectifier 100 is electrically connected with a positive terminal of a car battery 102, whereby the resistance of current loop of car is reduced.

As shown in FIG. 5, the quantum superconductor rectifier 100 is electrically connected with a negative terminal of a car battery 102, and is furthermore electrically connected with the car body 103 whereby the resistance of current loop of car is reduced.

As shown in FIG. 6-7 the present invention is applied to not only optimization of current loop in car, but also electrical equipment in family, factory and other places. As shown in FIG. 6, the quantum superconductor rectifier 100 is set around power wires, ground wires in an electric box 104. However, if a general user cannot distinguish which are the power wires, he can put several wires and carrier 1 in electric box together. Since the quantum superconductor rectifier 100 is not electrically connected with various wires in electric box, thereby no leakage current is generated.

As shown in FIG. 7, the quantum superconductor rectifier 100 is set around wires of an electric equipment 105. If it is set nearer to the electric equipment 105, is more efficient to reduce resistance in the current loop of electric equipment.

Since the signal of nuclear magnetic resonance of the quantum superconductor rectifier 100 is quantized, resistance in the current loop is also reduced, even if battery, electric box or electric equipment are not electrically connected therewith, whereby the quantum superconductor rectifier can be directly set around, or tied to the wires.

1. A quantum superconductor rectifier comprises:
a carrier, in definite shape; wherein atomic nuclei in components of said carrier are excited to vibration by a strong magnetic field, when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken,
whereby interference by electrical resistance is reduced and more effectiveness is achieved.

2. The quantum superconductor rectifier of claim 1, wherein said carrier is consisted of metallic materials.

3. The quantum superconductor rectifier of claim 2, wherein the said carrier is consisted of copper alloy, aluminum alloy or titanium alloy.

4. The quantum superconductor rectifier of claim 1, wherein said carrier is covered with a case; wherein the said case is made of insulation materials.

5. The quantum superconductor rectifier of claim 4, wherein said quantum superconductor rectifier is inserted in a cigarette lighter in car.

6. The quantum superconductor rectifier of claim 4, wherein said quantum superconductor rectifier electrically connected with a positive terminal of a car battery.

7. The quantum superconductor rectifier of claim 4, wherein said quantum superconductor rectifier is electrically connected with a positive terminal of a car battery and is with the car body.

8. The quantum superconductor rectifier of claim 1, wherein said quantum superconductor rectifier is set around power wires of an electric box.

9. The quantum superconductor rectifier of claim 1, wherein said quantum superconductor rectifier is set around the wires of electrical equipment.

10. A manufacturing method for a quantum superconductor rectifier, applied to manufacturing any quantum superconductor rectifier of claims 1 comprises the following steps:
(a) setting at least a carrier in the radio frequency field of an electromagnetic equipment, wherein a strong magnetic field is generated by the electromagnetic equipment, whereby atomic nuclei in components of said carrier are excited to vibration;
(b) after a definite period, when the cumulative atomic nuclei in components of said carrier transmit nuclear spectra, energy is quantized and a signal from nuclear magnetic resonance results as a strong cutting line, wherein overloaded conductive molecules in a current loop are cut and separated and wherein the Van der Waals forces between the molecules are broken.
whereby interference by electrical resistance is reduced and more effectiveness is achieved.
